(19) United States
(12) Patent Application Publication
(10) Pub. No.: US 2009/0184779 A1
(43) Pub. Date: Jul. 23, 2009

(54) WIRELESS COMMUNICATION MODULE

(75) Inventors: Yun Hee CHO, Suwon (KR); Yun Hwi PARK, Yongin (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/336,102

(22) Filed: Dec. 16, 2008

(30) Foreign Application Priority Data
Jan. 23, 2008 (KR) 10-2008-0007189
Jan. 23, 2008 (KR) 10-2008-0007190

(51) Int. Cl. H03H 5/00

(52) U.S. Cl. 333/26; 333/25

(57) ABSTRACT

A wireless communication module includes a laminated substrate where a plurality of dielectric sheets are laminated, a band pass filter, a balun circuit, and first and second matching circuits. The band pass filter is formed in the laminated substrate. The balun circuit is formed in the laminated substrate, and includes an unbalanced element having one end connected to the band pass filter. The first and second matching circuits are formed in the laminated substrate, and each of them is connected to one end of each of balanced elements of the balun circuit. Herein, at least one of the band pass filter, the balun circuit, the first matching circuit, and the second matching circuit is formed between the dielectric sheets of the laminated substrate using a distributed element.

### CROSS-REFERENCE TO RELATED APPLICATIONS

This application claims the priority of Korean Patent Application No. 2008-0007189 and 2008-0007190 filed on Jan. 23, 2008, in the Korean Intellectual Property Office, the disclosure of which is incorporated herein by reference.

### BACKGROUND OF THE INVENTION

1. Field of the Invention

The present invention relates to a wireless communication module, and more particularly, to a wireless communication module that can be miniaturized by forming a plurality of parts in a laminated substrate.

2. Description of the Related Art

Advances in technology for wireless communication devices such as cell phones accelerate the development of various kinds of wireless communication devices, and there is an increasing demand for miniaturization and slimness to maximize the efficiency of the wireless communication device.

To meet the demand for miniaturization and slimness of the wireless communication device, a new technique has been introduced, where parts are formed inside a laminated substrate where a plurality of dielectric sheets are laminated. Meanwhile, various attempts continue to be made to minimize a physical volume in the case of forming the parts inside the laminated substrate.

### SUMMARY OF THE INVENTION

An aspect of the present invention provides a structure and an arrangement required for miniaturizing parts formed inside a laminated substrate.

According to another aspect of the present invention, there is provided a wireless communication module including: a laminated substrate where a plurality of dielectric sheets are laminated; a band pass filter formed in the laminated substrate; a balun circuit formed in the laminated substrate, and including an unbalanced element having one end connected to the band pass filter; and first and second matching circuits formed in the laminated substrate, each being connected to one end of each of balanced elements of the balun circuit, wherein at least one of the band pass filter, the balun circuit, the first matching circuit, and the second matching circuit is formed between the dielectric sheets of the laminated substrate using a distributed element.

In the balun circuit, a balanced current generated by capacitance coupling between the unbalanced element and one of the balanced elements may flow through the other one of the balanced elements.

The balun circuit may include: an unbalanced element formed on one of the dielectric sheets of the laminated substrate; a first balanced element formed on the one of the dielectric sheets and another one of the dielectric sheets so as to form a capacitance coupling with the unbalanced element, and having one end connected to the first matching circuit; and a second balanced element formed on the one of the dielectric sheets and another one of the dielectric sheets, and having one end connected to the first balanced element and the other end connected to the second matching circuit.

The wireless communication module may further include a ground plane formed between the unbalanced element and the second balanced element and preventing the capacitor coupling between the unbalanced element and the second balanced element.

Each of the unbalanced element, the first balanced element and the second balanced element may have a length of λ/4.

The band pass filter may include: first and second resonators including first and second inductor patterns which are symmetrically formed on one of the dielectric sheets of the laminated substrate, and first and second capacitor patterns which are symmetrically formed on another one of the dielectric sheets so as to partially or fully overlap the first and second inductor patterns; and first and second load capacitor patterns, each being capacitively coupled to one end of each of the first and second resonators, wherein each of the first and second inductor patterns comprises a low impedance part having a wide line, and a high impedance part that extends from the low impedance part and has a meander-shaped narrow line.

The band pass filter may further include first and second notch capacitor patterns, each being capacitively coupled to the other end of each of the first and second resonators electrically.

The first and second notch capacitor patterns may be capacitively coupled to the high impedance parts of the first and second resonators, respectively.

According to another aspect of the present invention, there is provided a wireless communication module including: a substrate including a first laminated region where at least one of first dielectric sheets having a first permittivity is laminated, and a second laminated region where at least one of second dielectric sheets having a second permittivity is laminated, the second permittivity being lower than the first permittivity; a capacitor formed in the first laminated region of the substrate; a band pass filter formed in the second laminated region of the substrate; and a balun circuit formed in the second laminated region of the substrate, and connected to the band pass filter, wherein at least one of the band pass filter and the balun circuit is formed using a distributed element.

The first permittivity may have a dielectric constant (εᵣ) of approximately 500 or higher.

The second permittivity may have a dielectric constant (εᵣ) of approximately 10 or lower.

The wireless communication module may further include a buffer layer laminated between the first laminated region and the second laminated region.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a sectional view of a wireless communication module according to an embodiment of the present invention;

FIG. 2 is a structural diagram of a balun circuit used in a wireless communication module according to an embodiment of the present invention;

FIG. 3 is an exploded perspective view of a band pass filter used in a wireless communication module according to an embodiment of the present invention;

FIG. 4 is an equivalent circuit diagram of the band pass filter of FIG. 3;

FIG. 5 is a sectional view of a wireless communication module according to another embodiment of the present invention; and

FIG. 6 is a sectional view of a capacitor used in a wireless communication system according to another embodiment of the present invention.

### DETAILED DESCRIPTION OF THE PREFERRED EMBODIMENT

Exemplary embodiments of the present invention will now be described in detail with reference to the accompanying drawings.

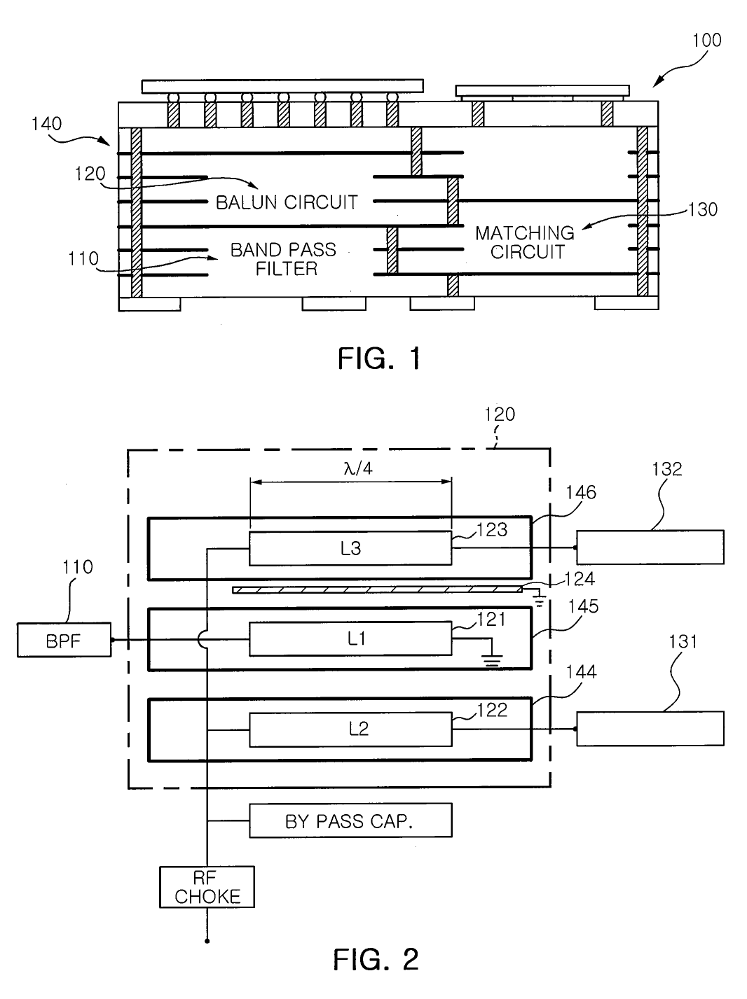

FIG. 1 is a sectional view of a wireless communication module according to an embodiment of the present invention.

Referring to FIG. 1, the wireless communication module 100 according to this embodiment includes a laminated substrate 140, a band pass filter 110, formed in the laminated substrate 140, a balun circuit 120, and a matching circuit 130.

The laminated substrate 140 may includes a plurality of dielectric sheets which are laminated.

A circuit pattern connecting internal circuits may be formed on each of the plurality of dielectric sheets forming the laminated substrate 140. A conductive via may be formed in each of the dielectric sheets to electrically connect elements interposed between the dielectric sheets. A semiconductor device may be mounted on the surface of the laminated substrate 140, and may be connected to the circuit pattern formed in the laminated substrate 140 through the conductive via.

The dielectric sheets may employ a glass-based dielectric substrate formed of, for example, glass epoxy resin. A conductive pattern formed on the dielectric sheet may include a conductive material such as copper. Alternatively, the laminated substrate 140 may be formed in such a way that various kinds of conductive patterns are provided on inorganic-based dielectric sheets formed of a ceramic material, and the dielectric sheets are then laminated and sintered together.

The relative permittivity of a ceramic dielectric is in the range of 7 to 25 in general, which is higher than that of a resin substrate. Therefore, if the dielectric sheet is formed of a ceramic material, the dielectric sheet can be thinned, an embedded circuit formed between the dielectric sheets can be downsized, and a distance between elements can be narrowed.

In particular, the conductive pattern may be formed of a low resistance material such as copper and silver in case of using a ceramic material, e.g., glass ceramics, which can be sintered at a low temperature. In addition, the conductive via may be formed by plating an inner surface of a through hole formed in the dielectric sheet or filling a conductive paste into the through hole.

The bandpass filter 110 may be formed using distributed elements. To form the band pass filter, predetermined inductor patterns and capacitor patterns may be formed between the laminated dielectric sheets of the laminated substrate.

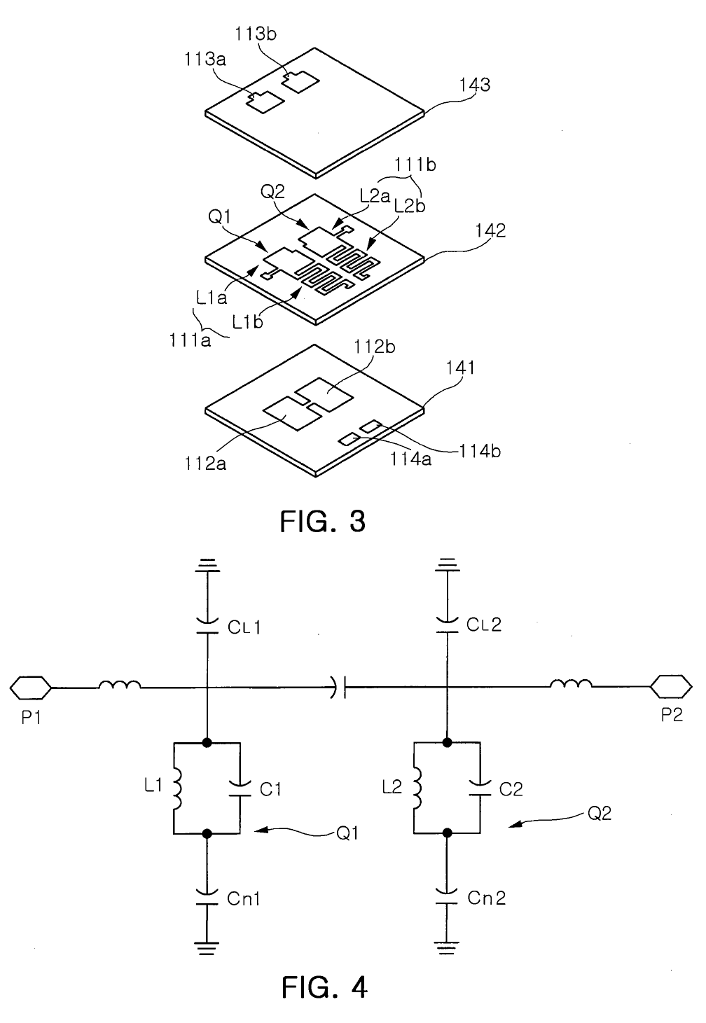

In this embodiment, the inductor patterns and the capacitor patterns forming the band pass filter 110 are implemented with distributed elements, thus reducing a size of the band pass filter 110. Specific embodiments of the band pass filter 110 formed using the distributed elements will be more fully detailed with reference to FIG. 3.

The balun circuit 120 may include one unbalanced element and two balanced elements. In general, the balun circuit 120 may output a signal that is input to one unbalanced element to two balanced elements, or may output signals that are input to two balanced elements to one balanced element. At this time, the signals output from the two balanced elements may have the same amplitude but has a phase difference of 180° therebetween.

In this embodiment, the unbalanced element is connected to the band pass filter 110, and an unbalanced current flowing through the unbalanced element may induce a balanced current in one of the two balanced elements. Since the two balanced elements are connected to each other, the balanced current, which is induced in the one balanced current, may flow into the other of the balanced elements.

In this embodiment, the unbalanced element and the two balanced elements forming the balun circuit 120 are implemented with distributed elements, thereby reducing a size of the balun circuit 120. Specific embodiments of the balun circuit formed using distributed elements will be described in detail with reference to FIG. 2.

The matching circuit 130 is connected to the balun circuit 120, and provides impedance matching between an output terminal of the balun circuit 120 and an input terminal of an integrated circuit (IC). The matching circuit 130 may include first and second matching circuits, and the first and second matching circuits may be respectively connected to ends of the balanced elements of the balun circuit.

In this embodiment, the matching circuit is implemented with distributed elements, which can reduce a size of the wireless communication module including the matching circuit.

FIG. 2 is a structural diagram of a balun circuit used in a wireless communication module according to an embodiment of the present invention.

Referring to FIG. 2, the balun circuit 120 may include an unbalanced element 121, a first balanced element 122, a second balanced element 123, and a ground plane 124.

In this embodiment, the unbalanced element 121, and the first and second balanced elements 122 and 123 may be formed on dielectric sheets 145, 144 and 146 of the laminated substrate, respectively.

One end of the unbalanced element 121 may be connected to the band pass filter 110, and the other end may be connected to the ground plane 124.

The first balanced element 122 may be formed such that it overlaps the unbalanced element 121 so as to be capacitively coupled to the unbalanced element 121. In this embodiment, the first balanced element 122 may be formed on the dielectric sheet 145 with the unbalanced element formed and the dielectric sheet 145.

One end of the first balanced element 122 may be connected to one end of the second balanced element 123, and the other end of the first balanced element 122 may be connected to the first matching circuit 131.

The unbalanced element 121 and the first balanced element 122 are capacitively coupled to each other so that a balanced current may be induced in the first balanced element by an unbalanced current flowing through the unbalanced element 121.

One end of the second balanced element 123 may be connected to the first balanced element 122, and the other end may be connected to the second matching circuit 132.

The balanced current induced in the first balanced element 122 also flows through the second balanced element 123. In this embodiment, the first and second balanced elements may be formed to have a length of λ/4. Therefore, signals output to the first and second matching circuits may have the same amplitude and a phase difference of 180° therebetween.

The ground plane 124 may be formed between the second balanced element 123 and the unbalanced element 121. The ground plane 124 may prevent the capacitance coupling between the second balanced element 123 and the unbalanced element 121. Accordingly, the balanced current induced in the first balanced element 122 may not be externally affected while flowing through the second balanced element 123.

FIG. 3 is an exploded perspective view of the band pass filter 110 used in the wireless communication module according to an embodiment of the present invention.

Referring to FIG. 3, the bandpass filter 110 may include first and second resonators Q1 and Q2, and load capacitor patterns 113a and 113b.

The first resonator Q1 may include an inductor pattern 111a formed on the top surface of the dielectric sheet 142, and a capacitor pattern 112a formed on the top surface of the dielectric sheet 141. The capacitor pattern 112a is formed such that at least a portion of the capacitor pattern 112a may overlap the inductor pattern 111a. The inductor pattern 111a may include a low impedance part L1a having a wide line, and a high impedance part L1b having a meander-shaped narrow line.

Likewise, the second resonator Q2 may include an inductor pattern 111b formed on the top surface of the dielectric sheet 142, and a capacitor pattern 112b formed on the top surface of the dielectric sheet 141. The capacitor pattern 112b is formed such that at least a portion of the capacitor pattern 112b may overlap the inductor pattern 111b. The inductor pattern 111b may include a low impedance part L2a having a wide line, and a high impedance part L2b having a meander-shaped narrow line.

The inductor pattern 111a and the capacitor pattern 112a included in the first resonator Q1, and the inductor pattern 111b and the capacitor pattern 112b included in the second resonator Q2 are symmetrically formed in parallel with each other.

In this embodiment, a step impedance resonator in which the inductor pattern has a wide portion and a narrow portion is used to thereby maintain a constant ratio of impedance between the high impedance part and the low impedance part. This makes it possible to improve rejection characteristic in a range except for a pass band. Since the high impedance part is meander-shaped, a total size of the filter can be reduced.

That is, the resonator according to this embodiment can be manufactured such that the inductor pattern having a length of λ/4 corresponding to a frequency allowing a signal to pass is formed not to have the same area throughout, but to have a wider portion and a narrow portion which are connected to each other. Compared to a typical filter having a resonator with the same area, the filter according to this embodiment is advantageous in that an additional structure is not required because the rejection characteristic at a predetermined band around a center frequency is excellent, and also a physical size can be reduced because a narrow portion can be formed in the shape of a meander.

The first and second resonators Q1 and Q2 may be electrically coupled to each other by the load capacitor patterns 113a and 113b. That is, there occurs a capacitor coupling between ends of lines of the low impedance parts L1a and L2a of the resonators Q1 and Q2 and the load capacitor patterns 113a and 113b, thereby forming load capacitance. Herein, each of the load capacitor patterns 113a and 113b may be connected to a ground (not shown).

In this way, when the load capacitor patterns 113a and 113b are connected to the low impedance parts L1a and L2a of the resonators Q1 and Q2, it is possible to improve the rejection characteristic of a high-frequency band and further reduce a length of the resonator having the length of λ/4.

In this embodiment, notch capacitor patterns 114a and 114b may be further provided to be capacitively coupled to the resonators Q1 and Q2.

The notch capacitor patterns 114a and 114b are capacitively coupled to the high impedance parts L1b and L2b of the resonators Q1 and Q2 to thereby form notch capacitance, and each of the notch capacitor patterns 114a and 114b may be connected to a ground. Such a configuration of the notch capacitor allows the rejection characteristic of a low-frequency band of the filter to be increased.

FIG. 4 is an equivalent circuit diagram of the band pass filter of FIG. 3.

Referring to FIG. 4, an inductor L1 and a capacitor C1 forming the first resonator Q1 may respectively represent an inductance of the first inductor pattern 111a and a capacitance formed between the first inductor pattern 111a and the capacitor pattern 112a in FIG. 3.

A load capacitor CL1 in FIG. 4 may represent a capacitance formed between the low impedance part L1a of the first inductor pattern and the load capacitor pattern 113a in FIG. 3.

A notch capacitor Cn1 in FIG. 4 may represent a capacitance formed between the high impedance part L1b of the first inductor pattern and notch capacitor pattern 114a.

An inductor L2 and a capacitor C2 forming the second resonator Q2 in FIG. 4 may represent an inductance of the second inductor pattern 111b and a capacitance between the second inductor pattern 111b and the capacitor pattern 112b in FIG. 3.

A load capacitor CL2 in FIG. 4 may represent a capacitance formed between the low impedance part L2a of the second inductor pattern and the load capacitor pattern 113b in FIG. 3.

A notch capacitor Cn2 in FIG. 4 may represent a capacitance between the high impedance part L2b of the second inductor pattern and the notch capacitor pattern 114a.

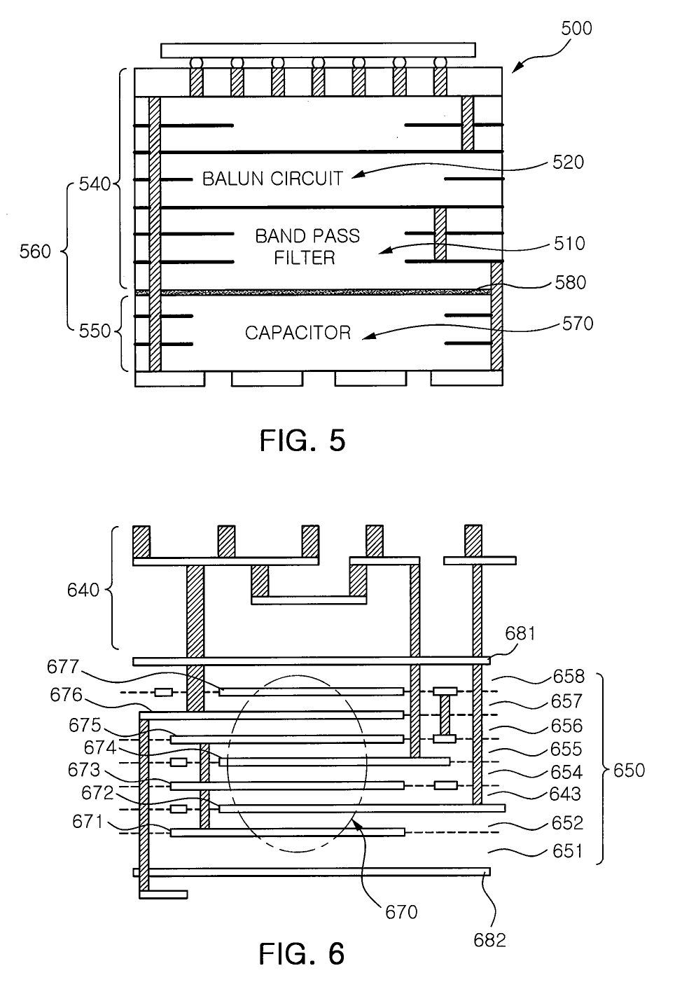

FIG. 5 is a sectional view of a wireless communication module according to another embodiment of the present invention.

Referring to FIG. 5, the wireless communication module 500 according to this embodiment may include a laminated substrate 560 provided with a first laminated region 550 and a second laminated region 540, a capacitor formed in the first laminated region 550, a band pass filter 510 formed in the second laminated region 540, and a balun circuit 520. Here, a first dielectric sheet is formed in the first laminated region 550, and a second dielectric sheet is formed in the second laminated region 540.

As described above, the laminated substrate 560 may be divided into two regions, of which one is the first laminated region 550 where the first dielectric sheet is formed, and the other is the second laminated region where the second dielectric sheet is formed.

The first laminated region 550 may include a plurality of first dielectric sheets having a first permittivity that are laminated. In this embodiment, the first dielectric sheet may have a high permittivity of which a dielectric constant (Er) is approximately 500 or higher.

The second laminated region 540 may include a plurality of second dielectric sheets having a second permittivity that are laminated. In this embodiment, the second dielectric sheet may have a low permittivity of which a dielectric constant (Er) is approximately 10 or lower.

A circuit pattern connecting internal circuits may be formed on each of the plurality of dielectric sheets forming the laminated substrate 560. A conductive via may be formed in each of the dielectric sheets to electrically connect elements interposed between the dielectric sheets. A semiconductor device may be mounted on the surface of the laminated substrate 560, and may be connected to the circuit pattern formed in the laminated substrate 50 through the conductive via.

The dielectric sheets may employ a glass-based dielectric substrate formed of, for example, glass epoxy resin. A conductive pattern formed on the dielectric sheet may include a conductive material such as copper. Alternatively, the laminated substrate 560 may be formed in such a way that various kinds of conductive patterns are provided on inorganic-based dielectric sheets formed of a ceramic material, and the dielectric sheets are then laminated and sintered together.

The laminated substrate 560 may further include a buffer layer 580 between the first laminated region 550 and the second laminated region 540.

The buffer layer 580 can prevent a high permittivity material of the first dielectric sheet of the first laminated region 550 and a low permittivity material of the second dielectric sheet of the second laminated region 540 from being mixed.

The capacitor 570 may be achieved by forming electrodes facing each other between the dielectric sheets formed in the first laminated region 550 of the laminated substrate 560. The facing electrodes are connected such that they have different polarities, and capacitance can be produced due to the permittivity of the first dielectric sheet interposed between the electrodes.

In this embodiment, since the first dielectric sheet is higher in permittivity than the second dielectric sheet, it is possible to realize a high capacitance capacitor formed in the first laminated region 550.

The bandpass filter 510 may be formed using distributed elements. To form the band pass filter 510, predetermined inductor patterns and capacitor patterns may be formed between the laminated dielectric sheets formed in the second laminated region 540 of the laminated substrate 560.

In this embodiment, the inductor patterns and the capacitor patterns forming the band pass filter 510 are implemented with distributed elements, so that a size of the band pass filter 510 cab be reduced.

The balun circuit 520 may include one unbalanced element and two balanced elements. In general, the balun circuit 520 may output a signal that is input to one unbalanced element to two balanced elements, or may output signals that are input to two balanced elements to one balanced element. At this time, the signals output from the two balanced elements may have the same amplitude but has a phase difference of 180° therebetween.

In this embodiment, the unbalanced element is connected to the band pass filter 510, and an unbalanced current flowing through the unbalanced element may induce a balanced current in one of the two balanced elements. The two balanced elements are connected to each other, and thus the balanced current, which is induced in the one balanced current, may flow to the other of the balanced elements.

In this embodiment, the unbalanced element and the two balanced elements forming the balun circuit 520 are implemented with distributed elements, thereby reducing a size of the balun circuit. The balun circuit 520 may be formed in the second laminated region 540 of the laminated substrate 560. Specific embodiments of the balun circuit 520 formed using distributed elements have been described already with reference to FIG. 2.

Consequently, in the wireless communication module according to this embodiment, number of elements externally mounted can be reduced by forming the band pass filter, the balun circuit, and the capacitor in the laminated substrate, which leads to a decrease in fabrication cost and defects during mass production. In addition, since the capacitor is formed between the dielectric sheets with high permittivity, the capacitor the according to this embodiment can be formed to have a smaller size and higher capacitance than a typical embedded capacitor. Hence, overall module characteristics can be stably realized.

FIG. 6 is a sectional view of a capacitor used in a wireless communication system according to another embodiment of the present invention.

Referring to FIG. 6, capacitors 670 according this embodiment are formed between the first dielectric sheets 652, 653, 654, 655, 656 and 657 having a first permittivity, and include a plurality of electrodes 671, 672, 673, 674, 675, 676 and 677 connected to different polarity terminals, respectively.

In this embodiment, the electrodes formed between the first dielectric sheets may be formed such that they have different polarities. In this embodiment, the electrodes 671, 673, 675 and 677 are connected to a ground, and the other electrodes 672, 674 and 676 are connected to a power supply. In this embodiment, the first dielectric sheet may have a high permittivity of which a dielectric constant (Er) is approximately 500 or higher. Accordingly, the capacitor formed by the electrode can be realized so as to have high capacitance.

A buffer layer 681 may be further provided between a first laminated region 650 where the first dielectric sheet is formed and a second laminated region 640 where a second dielectric sheet is formed. The buffer layer 681 can prevent a high permittivity ceramic material of the first laminated region 650 and a low permittivity ceramic material of the second laminated region 640 from being mixed.

Furthermore, the buffer layer 682 may be formed on an exposed side of the first laminated region 650 such that the first laminated region 650 is not exposed to the outside. According to the present invention, it is possible to miniaturize a wireless communication module by forming smaller-sized electronic parts inside a laminated substrate.

While the present invention has been shown and described in connection with the exemplary embodiments, it will be apparent to those skilled in the art that modifications and variations can be made without departing from the spirit and scope of the invention as defined by the appended claims.

What is claimed is:

1. A wireless communication module comprising:
a laminated substrate where a plurality of dielectric sheets are laminated;
a band pass filter formed in the laminated substrate;
a balun circuit formed in the laminated substrate, and comprising an unbalanced element having one end connected to the band pass filter; and
first and second matching circuits formed in the laminated substrate, each being connected to one end of each of balanced elements of the balun circuit,
wherein at least one of the band pass filter, the balun circuit, the first matching circuit, and the second matching circuit is formed between the dielectric sheets of the laminated substrate using a distributed element.

2. The wireless communication module of claim 1, wherein, in the balun circuit, a balanced current generated by capacitance coupling between the unbalanced element and one of the balanced elements flows through the other one of the balanced elements.

3. The wireless communication module of claim 2, wherein the balun circuit comprises:
an unbalanced element formed on one of the dielectric sheets of the laminated substrate;
a first balanced element formed on the one of the dielectric sheets and another one of the dielectric sheets so as to form a capacitance coupling with the unbalanced element, and having one end connected to the first matching circuit; and
a second balanced element formed on the one of the dielectric sheets and another one of the dielectric sheets, and having one end connected to the first balanced element and the other end connected to the second matching circuit.

4. The wireless communication module of claim 3, further comprising a ground plane formed between the unbalanced element and the second balanced element, and preventing the capacitor coupling between the unbalanced element and the second balanced element.

5. The wireless communication module of claim 3, wherein each of the unbalanced element, the first balanced element and the second balanced element has a length of λ/4.

6. The wireless communication module of claim 1, wherein the band pass filter comprises:
first and second resonators comprising first and second inductor patterns which are symmetrically formed on one of the dielectric sheets of the laminated substrate, and first and second capacitor patterns which are symmetrically formed on another one of the dielectric sheets so as to partially or fully overlap the first and second inductor patterns; and
first and second load capacitor patterns, each being capacitively coupled to one end of each of the first and second resonators,
wherein each of the first and second inductor patterns comprises a low impedance part having a wide line, and a high impedance part that extends from the low impedance part and has a meander-shaped narrow line.

7. The wireless communication module of claim 6, further comprising first and second notch capacitor patterns, each being capacitively coupled to the other end of each of the first and second resonators electrically.

8. The wireless communication module of claim 7, wherein the first and second notch capacitor patterns are capacitively coupled to the high impedance parts of the first and second resonators, respectively.

9. A wireless communication module comprising:
a substrate comprising a first laminated region where at least one of first dielectric sheets having a first permittivity is laminated, and a second laminated region where at least one of second dielectric sheets having a second permittivity is laminated, the second permittivity being lower than the first permittivity;
a capacitor formed in the first laminated region of the substrate;
a band pass filter formed in the second laminated region of the substrate; and
a balun circuit formed in the second laminated region of the substrate, and connected to the band pass filter,
wherein at least one of the band pass filter and the balun circuit is formed using a distributed element.

10. The wireless communication module of claim 9, wherein the first permittivity has a dielectric constant (Er) of approximately 500 or higher.

11. The wireless communication module of claim 9, wherein the second permittivity has a dielectric constant (Er) of approximately 10 or lower.

12. The wireless communication module of claim 9, further comprising a buffer layer laminated between the first laminated region and the second laminated region.
